(19) United States
(12) Patent Application Publication
(10) Pub. No.: US 2025/0248277 A1
(43) Pub. Date: Jul. 31, 2025

(54) DISPLAY PANEL ASSEMBLY, DISPLAY DEVICE, AND METHOD FOR MANUFACTURING THE SAME

(71) Applicant: Samsung Display Co., LTD., Yongin-si (KR)

(72) Inventors: JONGHYEON CHOI, Yongin-si (KR); SUNGKOOK LEE, Yongin-si (KR); JEONGHO HWANG, Yongin-si (KR)

(21) Appl. No.: 19/004,391

(22) Filed: Dec. 29, 2024

(30) Foreign Application Priority Data
Jan. 26, 2024 (KR) 10-2024-0012140

(51) Int. Cl. H10K 59/80; H10K 59/12

(52) U.S. Cl. CPC H10K 59/873; H10K 59/1201

(57) ABSTRACT

A display device includes a display panel including a display region and a non-display region adjacent to the display region, a cover glass disposed on the display panel, an optical member disposed between the cover glass and the display panel, and overlapping the display region, a dummy member which is disposed between the cover glass and the display panel, in which an opening accommodating the optical member is defined, and which overlaps the non-display region, and an adhesive member disposed between the optical member and the display panel, and spaced apart from the dummy member.

This application claims priority to Korean Patent Application No. 10-2024-0012140, filed on Jan. 26, 2024, and all the benefits accruing therefrom under 35 U.S.C. § 119, the content of which in its entirety is herein incorporated by reference.

### BACKGROUND

### 1. Field

The disclosure herein relates to a display panel assembly, a display device, and a method for manufacturing the same, and more particularly, to a display device including an optical unit.

### 2. Description of the Related Art

A display device, such as a television, a monitor, a smartphone, and a tablet computer, which provide images to a user, includes a display panel which displays images. Various display panels such as a liquid crystal display panel, an organic light-emitting display panel, an electrowetting display panel, and an electrophoretic display panel are being developed as display panels. Additionally, the display device may include a window for protecting the display panel. The window may be attached to the display panel through a lamination process.

### SUMMARY

The disclosure provides a display device including a cover glass coated on a display panel.

An embodiment of the inventive concept provides a display panel assembly including: a display panel including a display region and a non-display region adjacent to the display region; a preliminary cover glass disposed on the display panel; an optical member disposed between the preliminary cover glass and the display panel, and overlapping the display region; and a preliminary dummy member which is disposed between the preliminary cover glass and the display panel, and in which an opening accommodating the optical member is defined. The preliminary dummy member includes a first dummy portion which overlaps the non-display region and in which the opening is defined, a second dummy portion extending, from the first dummy portion, a direction of getting farther away from the opening, and not overlapping the display panel.

In an embodiment, the preliminary cover glass may be in direct contact with the optical member and the preliminary dummy member.

In an embodiment, the preliminary dummy member and the optical member may include different materials from each other.

In an embodiment, a light transmittance of the preliminary dummy member may be smaller than or equal to a light transmittance of the optical member.

In an embodiment, a sum of a first width of the first dummy portion and a second width of the second dummy portion may be 4 millimeters (mm) to 10 mm.

In an embodiment, the display panel assembly may further include an adhesive member disposed between the optical member and the display panel. The adhesive member may be spaced apart from the preliminary dummy member.

In an embodiment, the display panel assembly may further include an electronic module disposed below the display panel. The electronic module may overlap the first dummy portion and not overlap the optical member.

In an embodiment, the first dummy portion may include a projection part protruding toward the optical member, the optical member may include a recessed part corresponding to the projection part, and the electronic module may overlap the projection part in a plan view.

In an embodiment, the preliminary cover glass may include: a flat portion of which an upper surface is defined as a flat surface by a first direction and a second direction crossing the first direction; and a projection portion which is connected to the flat portion, and of which an upper surface is defined as a projection surface protruding in a third direction crossing the first direction and the second direction, and the flat portion may overlap the first dummy portion, and the projection portion overlaps the second dummy portion.

In an embodiment of the inventive concept, a display device includes: a display panel including a display region and a non-display region adjacent to the display region; a cover glass disposed on the display panel; an optical member disposed between the cover glass and the display panel, and overlapping the display region; a dummy member in which an opening accommodating the optical member is defined, and which is disposed between the cover glass and the display panel and overlaps the non-display region; and an adhesive member disposed between the optical member and the display panel, and spaced apart from the dummy member.

In an embodiment, the cover glass may be in direct contact with the optical member and the dummy member.

In an embodiment, a side surface of the cover glass and a side surface of the dummy member may be substantially aligned.

In an embodiment, the display device may include an electronic module disposed below the display panel. The electronic module may overlap the dummy member and does not overlap the optical member.

In an embodiment, the dummy member may include a projection part protruding toward the optical member, the optical member may include a recessed part corresponding to the projection part, and the electronic module may overlap the projection part in a plan view.

In an embodiment, the dummy member and the optical member may include different materials from each other, and a light transmittance of the dummy member may be smaller than or equal to a light transmittance of the optical member.

In an embodiment of the inventive concept, a method for manufacturing a display device includes: disposing, on a preliminary dummy member, an optical member including a material different from that of the preliminary dummy member; defining an opening accommodating the optical member by removing a removal part of the preliminary dummy member; attaching, to a display panel, the preliminary dummy member in which the opening is defined and the optical member; forming a preliminary cover glass covering the preliminary dummy member in which the opening is defined and the optical member; and forming a cover glass and a dummy member by removing a portion of the preliminary cover glass not overlapping the display panel, and a portion of the preliminary dummy member in which the opening is defined.

In an embodiment, an interval between an inner side surface, of the preliminary dummy member, defining the opening, and an outer side surface, of the preliminary dummy member, opposed to the inner side surface may be 5 mm to 10 mm.

In an embodiment, on the preliminary cover glass, a flat portion overlapping the optical member and a projection portion overlapping the dummy member may be formed, and the projection portion and a portion of the preliminary dummy member overlapping the projection portion may be removed using first laser.

In an embodiment, the disposing the preliminary dummy member and the optical member on the display panel may include: moving the optical member and the preliminary dummy member onto the display panel by suctioning the optical member and the preliminary dummy member with a suction pad; and detaching the suction pad from the preliminary dummy member and the optical member, and then adhering the preliminary dummy member and the optical member to the display panel using a roller.

In an embodiment, in the defining the opening by removing a portion of the preliminary dummy member, the opening may be defined using second laser.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of a display device according to the inventive concept;

FIGS. 2A and 2B are exploded perspective views of an embodiment of a display device according to the inventive concept;

FIG. 3 is a plan view of an embodiment of a display panel according to the inventive concept;

FIG. 4 is a plan view of an embodiment of a touch-sensing panel according to the inventive concept;

FIG. 5 is a side view of an embodiment of a display device according to the inventive concept;

FIG. 6 is a cross-sectional view of an embodiment of an optical unit according to the inventive concept;

FIGS. 7A and 7B are plan views of an embodiment of an optical unit according to the inventive concept;

FIG. 8A is a plan view of an embodiment of a dummy member according to the inventive concept;

FIG. 8B is a plan view of an embodiment of n optical member according to the inventive concept;

FIG. 8C is a cross-sectional view of an embodiment of a display device according to the inventive concept; and

FIGS. 9A to 9F are cross-sectional views illustrating an embodiment of a method for manufacturing a display device according to the inventive concept.

### DETAILED DESCRIPTION

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thickness, the ratio, and the dimension of the elements are exaggerated for effective description of the technical contents. The term “and/or” includes all of one or more combinations defined by the associated elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

Also, the terms such as “below”, “lower”, “above”, “upper” and the like, may be used for the description to describe one element's relationship to another element illustrated in the drawing figures. It will be understood that the terms have a relative concept and are described on the basis of the orientation depicted in the drawing figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display panel in an embodiment of the inventive concept and a method for manufacturing the same will be described with reference to the accompanying drawings.

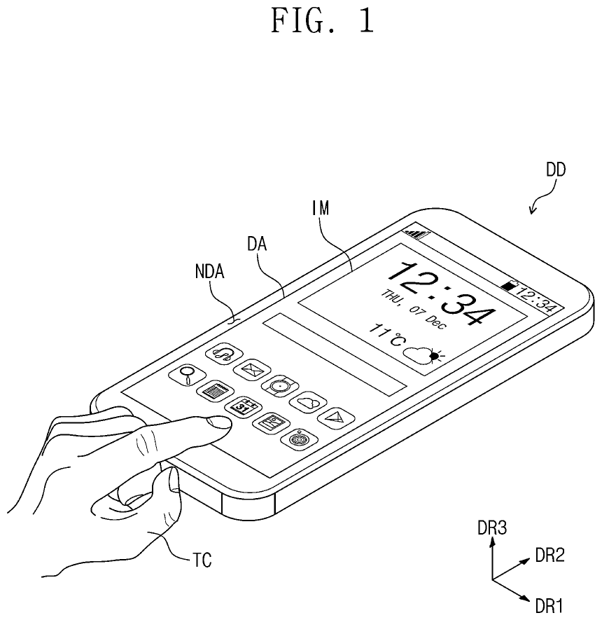

FIG. 1 is a perspective view of an embodiment of a display device according to the inventive concept.

Referring to FIG. 1, a portable terminal is illustrated in an embodiment of a display device DD according to the inventive concept. The portable terminal may include a tablet personal computer (“PC”), a smartphone, a personal digital assistant (“PDA”), a portable multimedia player (“PMP”), a game console, a wristwatch-type electronic device, or the like. However, the inventive concept is not limited thereto.

The display device according to the inventive concept may be used for large-sized electronic equipment such as a television or an outdoor billboard, as well as medium-and small-sized electronic equipment such as a personal computer, a laptop computer, a car navigation unit, or a camera. These are merely presented as examples, and the display device may also be employed to other electronic apparatuses without departing from the spirit of the inventive concept.

The display device DD may be flexible. The wording “flexible” means having a bendable property, and may include all of a completely foldable structure as well as a structure which is bendable to the level of several nanometers. In an embodiment, the flexible display device DD may include a curved display device, a foldable display device, a slidable display device, or a rollable display device, for example. However, the inventive concept is not limited thereto, and the display device DD may be rigid.

As illustrated in FIG. 1, a display surface on which an image IM is displayed is parallel to a surface defined by a first direction DR1 and a second direction DR2. The display device DD includes a plurality of regions defined on the display surface. The display surface includes a display region DA on which the image IM is displayed, and a non-display region NDA adjacent to the display region DA. The non-display region NDA may be also referred to as a bezel region. In an embodiment, the display region DA may have a quadrilateral shape. The non-display region NDA surrounds the display region DA, for example. Additionally, although not illustrated, the display device DD may include a partially curved shape, for example. As a result, one region of the display region DA may have a curved shape.

A front surface (or upper surface) and a rear surface (or lower surface) of each of members configuring the display device DD may be opposed to each other in a third direction DR3, and the normal direction of each of the front surface and the rear surface may be substantially parallel to the third direction DR3. A spacing distance between the front surface and the rear surface defined along the third direction

DR3 may correspond to a thickness of a member (or unit). In this specification, the wording “in a plan view” may be defined as a state when viewed in the third direction DR3. In this specification, the wording “in a cross-section” may be defined as a state when viewed in the first direction DR1 or the second direction DR2. The directions indicated by the first to third directions DR1 to DR3 have a relative concept, and may thus be changed to other directions. In this specification, “overlapping” may mean overlapping in a plan view, unless otherwise specified.

A front surface (or upper surface, or first surface) and a rear surface (or lower surface, or second surface) of each of members are defined based on a direction in which the image IM is displayed. However, the directions indicated by the first to third directions DR1 to DR3 may have a relative concept, and may thus be changed to other directions. Hereinafter, first to third directions are respectively indicated by the first to third directions DR1, DR2, and DR3, and thus denoted as the same reference numerals or symbols.

The display device DD in an embodiment of the inventive concept may detect a user's touch input TC applied from the outside. The user's touch input TC includes various types of external inputs such as a part of a user's body, light, heat, pen, or pressure. In this embodiment, it is described that the user's input is assumed to be a user's hand applied on a front surface. However, this is illustrative, and as described above, the user's input TC may be provided in various forms. Additionally, the display device DD may detect the user's input which is applied to a side surface or a rear surface of the display device DD according to a structure of the display device DD, and is not limited to a particular embodiment.

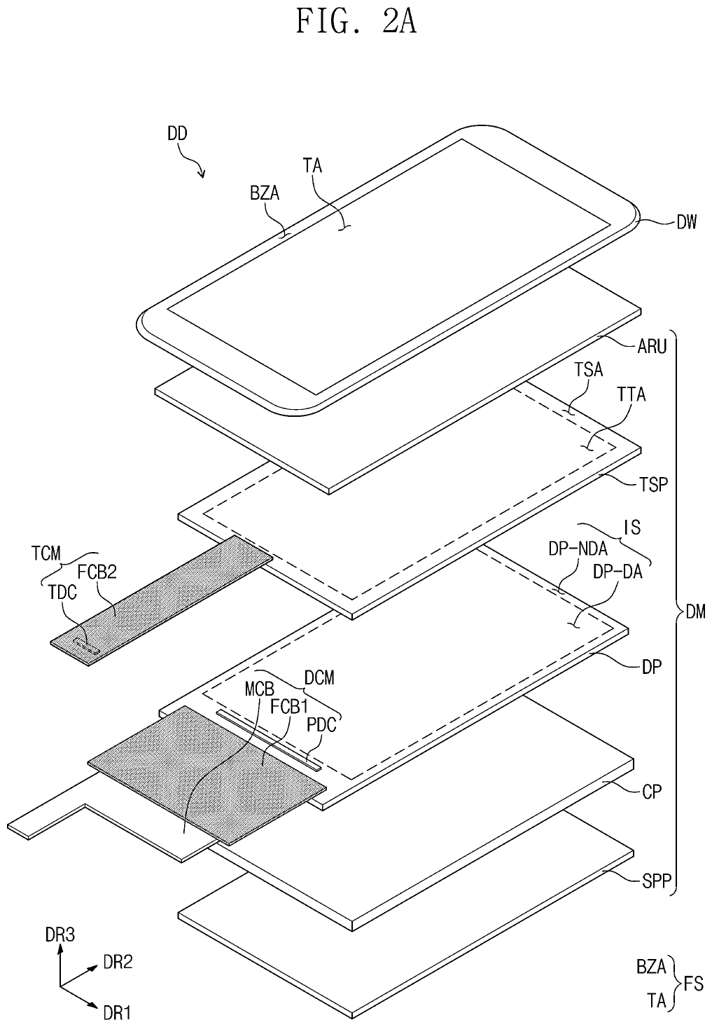

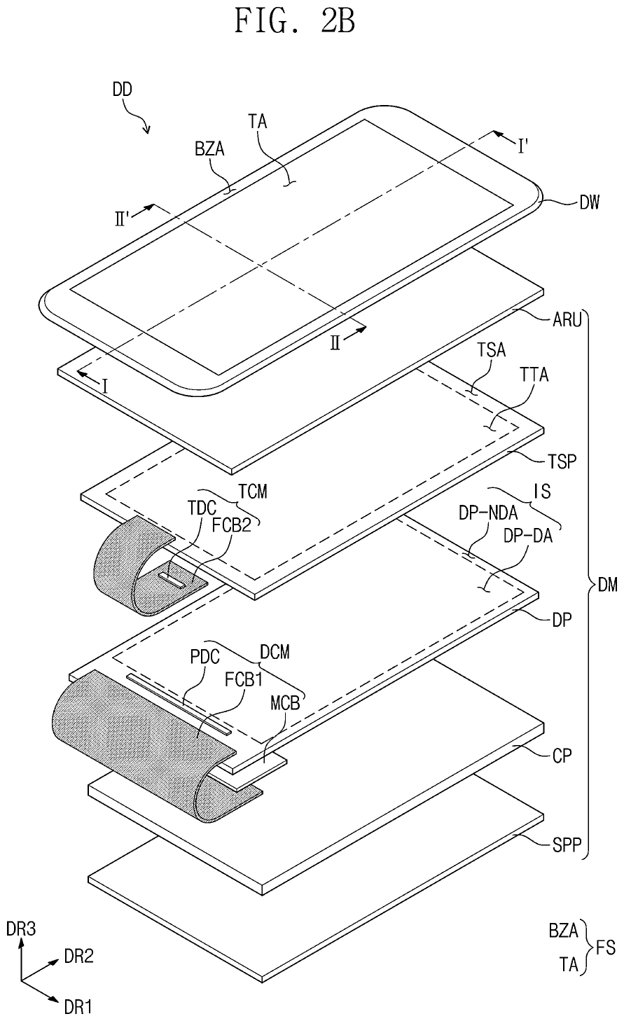

FIGS. 2A and 2B are exploded perspective views of an embodiment of a display device according to the inventive concept. More specifically, FIG. 2A is an exploded perspective view of a display device DD in which a first circuit board FCB1 (or first flexible board) and a second circuit board FCB2 (or second flexible board) are not bent, and FIG. 2B is an exploded perspective view of the display device DD in which the first circuit board FCB1 and the second circuit board FCB2 are bent.

Referring to FIGS. 2A and 2B, the display device DD may include a cover glass DW and a display module DM. The cover glass DW may be directly disposed on an optical unit ARU. In this case, the wording “being directly disposed” may mean being disposed without an additional adhesive or adhesive layer therebetween.

The cover glass DW may provide a front surface FS of the display device DD. The front surface FS of the cover glass DW may include a transmission region TA and a bezel region BZA. The transmission region TA of the cover glass DW may be an optically transparent region. The cover glass DW may transmit the image IM provided from the display panel DP through the transmission region TA, and the corresponding image IM (refer to FIG. 1) may be viewed by the user.

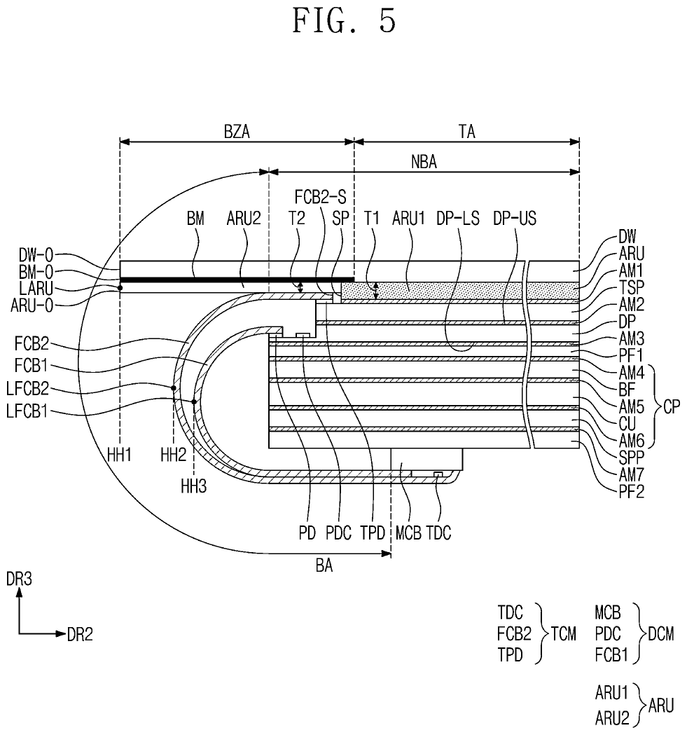

The bezel region BZA of the cover glass DW may overlap a light-blocking pattern BM (refer to FIG. 5) to be described later. The light-blocking pattern BM may be a rigid board including a material having a predetermined color. The bezel region BZA of the cover glass DW may prevent some components, of the display panel DP disposed to overlap the light-blocking pattern BM (refer to FIG. 5), from being viewed from the outside.

The bezel region BZA may be adjacent to the transmission region TA. A shape of the transmission region TA may be substantially defined by the bezel region BZA. In an embodiment, the bezel region BZA may be disposed outside the transmission region TA and surround the transmission region TA. However, this is illustrative, for example. The bezel region BZA may be adjacent only to one side of the transmission region TA or be omitted. Additionally, the bezel region BZA may be disposed not on a front surface, but on a side surface of the display device DD.

The cover glass DW may include an optically transparent insulating material. The cover glass DW may include a curable resin material. The cover glass DW may have a single-or multi-layered structure. In manufacture of the display device DD including the cover glass DW of the inventive concept, a lamination process of attaching a glass window to a panel may be omitted, thereby simplifying a manufacturing process of the display device DD and reducing costs.

The cover glass DW may include a functional coating layer such as an anti-fingerprint layer, an anti-reflection layer, and a hard coating layer. In this embodiment, the cover glass DW having a flat shape within a display region DP-DA is illustrated, but a shape of the cover glass DW may be deformed. Edges of the cover glass DW facing each other in the first direction DR1 may provide a curved surface.

The display module DM may be disposed on a rear surface of the cover glass DW and generate an image. Additionally, the display module DM may detect the user's input TC (refer to FIG. 1).

In this embodiment, the display module DM which provides a flat display surface is illustrated, but a shape of the display module DM may be deformed. Edges of the display module DM facing each other in the first direction DR1 may be bent from center portions and provide a curved surface.

The display module DM may include an optical unit ARU, a touch-sensing panel TSP, a display panel DP, a protective panel CP, a support panel SPP, and a driving control module DCM.

The optical unit ARU may be disposed on the display panel DP and overlap the display region DP-DA. The optical unit ARU may be disposed between the display panel DP and the cover glass DW. The optical unit ARU may reduce reflectance for light incident from the outside. The optical unit ARU may include at least one of a retarder, a polarizer, a polarizing film, or a polarizing filter. The optical unit ARU may be attached to the display panel DP via an adhesive layer. However, a type of optical unit ARU is illustrated and is not limited thereto. In an embodiment, the optical unit ARU may include a color filter, for example.

The optical unit ARU may serve as a base onto which a resin material may be applied to form the cover glass DW. That is, the optical unit ARU having a flat plate shape may be disposed below the cover glass DW, and a liquid resin material may be applied on the optical unit ARU. Additionally, the optical unit ARU covers, in a plan view, the bent flexible boards FCB1 and FCB2, and may thus prevent a resin material from flowing into the flexible boards FCB1 and FCB2 and being cured when applying the resin material. A resin material is prevented from flowing into the flexible boards FCB1 and FCB2 and being cured, and thus cracks may be prevented from occurring when the flexible boards FCB1 and FCB2 are bent during a bending process.

The display panel DP may be disposed between the cover glass DW and the support panel (also referred to as a support module) SPP. The display panel DP may display an image in response to an electrical signal. The display panel DP in an embodiment may be a light-emitting display panel, but is not particularly limited thereto. In an embodiment, the display panel DP may be an organic light-emitting display panel, an inorganic light-emitting display panel, an organic-inorganic light-emitting display panel, or a quantum dot light-emitting display panel, for example. A light-emitting layer of the organic light-emitting display panel may include an organic light-emitting material, and a light-emitting layer of the inorganic light-emitting display panel may include an inorganic light-emitting material. A light-emitting layer of the organic-inorganic light-emitting display panel may include an organic-inorganic light-emitting material. A light-emitting layer of the quantum dot light-emitting display panel may include quantum dots, quantum rods, or the like.

The image IM (refer to FIG. 1) provided from the display device DD may be displayed on a front surface IS of the display panel DP. The front surface IS of the display panel DP may include a display region DP-DA and a non-display region DP-NDA. In this case, the display region DP-DA may correspond to the display region DA of FIG. 1, and the non-display region DP-NDA may correspond to the non-display region NDA of FIG. 1.

The display region DP-DA may be a region which is activated in response to an electrical signal and displays images. In an embodiment, the display region DP-DA of the display panel DP may correspond to the transmission region TA of the cover glass DW. In this specification, the wording “a region/portion corresponds to a region/portion” means “the regions/portions overlapping each other” and is not limited to having the same area and/or shape.

The non-display region DP-NDA may be adjacent to the outside of the display region DP-DA. In an embodiment, the non-display region DP-NDA may surround the display region DP-DA, for example. However, the inventive concept is not limited thereto, and the non-display region DP-NDA may be defined as having various shapes.

The non-display region DP-NDA may be a region in which a driving circuit or a driving line for driving elements disposed in the display region DP-DA, various types of signal lines, pads, or the like for providing electrical signals may be disposed. The non-display region DP-NDA of the display panel DP may correspond to the bezel region BZA of the cover glass DW. The bezel region BZA may prevent components, of the display panel DP disposed in the non-display region DP-NDA, from being viewed from the outside.

The driving control module DCM includes a main circuit board MCB (or driving circuit board), a first circuit board FCB1, and a panel driving circuit PDC. The first circuit board FCB1 may be connected to a terminal portion of the display panel DP to electrically connect the main circuit board MCB and the display panel DP.

The panel driving circuit PDC may be disposed on the non-display region DP-NDA of the display panel DP. The panel driving circuit PDC may be configured as an integrated circuit. Although not illustrated separately, a plurality of passive elements and a plurality of active elements may be disposed (e.g., mounted) on the main circuit board MCB. The main circuit board MCB may be a rigid circuit board or a flexible circuit board, and the first circuit board FCB1 may be a flexible circuit board. The main circuit board MCB may be disposed on a rear surface of the display panel DP.

The first circuit board FCB1 may be disposed on the non-display region NDA of the display panel DP and be bent. The first circuit board FCB1 may be connected to a terminal portion of the display panel DP to electrically connect the main circuit board MCB and the display panel DP. One end of the first circuit board FCB1 may be disposed on a front surface of the display panel DP, and an opposite end may be bent so as to be disposed on the rear surface of the display panel DP. The first circuit board FCB1 may be bent, and one end thereof may be disposed on the rear surface of the display panel DP. A terminal of the first circuit board FCB1 may be opposed to a rear surface of the non-display region NDA in the third direction DR3. The main circuit board MCB may be disposed on the rear surface of the display panel DP.

The touch-sensing panel TSP may be disposed between the display panel DP and the optical unit ARU, and be connected to the second circuit board FCB2. Additionally, the touch-sensing panel TSP may acquire coordinate information about the user's input TC (refer to FIG. 1). The touch-sensing panel TSP may detect various types of inputs applied from the outside of the display device DD. In an embodiment, the touch-sensing panel TSP may detect an input by the user's body, but the inventive concept is not limited thereto. In an embodiment, the touch-sensing panel TSP may perceive various types of external inputs such as light, heat, or pressure, for example. Additionally, the touch-sensing panel TSP may detect an input contacting a sensing surface as well as an input adjacent to the sensing surface.

The touch-sensing panel TSP may be a capacitive touch panel, an electromagnetic induction touch panel, or the like. The touch-sensing panel TSP may include a base layer, sensing electrodes, and signal lines connected to the sensing electrodes.

A touch control unit TCM may include the second circuit board FCB2 and a touch driving circuit TDC. The second circuit board FCB2 may electrically connect the main circuit board MCB and the touch-sensing panel TSP, and have the touch driving circuit TDC disposed (e.g., mounted) thereon. The second circuit board FCB2 may be bent, similarly to the first circuit board FCB1. The second circuit board FCB2 may electrically connect the main circuit board MCB and the touch-sensing panel TSP. The touch driving circuit TDC may be configured as an integrated circuit. The second circuit board FCB2 may be a flexible circuit board.

The protective panel CP may be disposed on the rear surface of the display panel DP and protect the display panel DP against an impact. The protective panel CP may include a plastic film as a base layer. The protective panel (also referred to as a protective layer) CP may have a single-or a multi-layered structure.

The support panel SPP may be disposed on a rear surface of the protective panel CP and support the display panel DP and the protective panel CP. The support panel SPP may be a metal plate having a rigidity greater than a predetermined rigidity. The support panel SPP may be a stainless steel plate. The support panel SPP may have a black color so as to block external light incident onto the display panel DP.

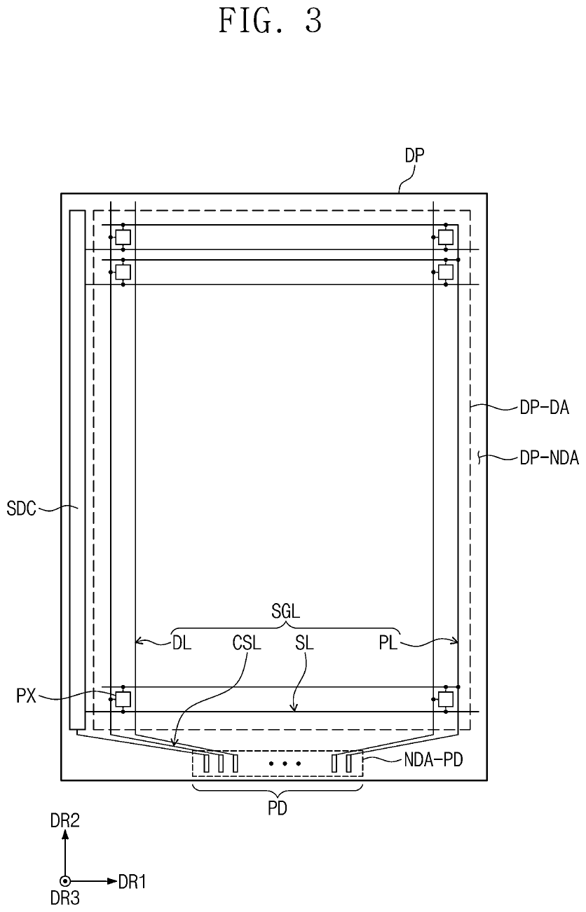

FIG. 3 is a plan view of an embodiment of a display panel according to the inventive concept. FIG. 3 briefly illustrates a signal circuit diagram. Additionally, in FIG. 3, some components are omitted for ease of description.

Referring to FIG. 3, a display panel DP may include, in a plan view, a display region DP-DA and a non-display region DP-NDA. In this embodiment, the non-display region DP-NDA may be defined along a border of the display region DP-DA. The display region DP-DA and the non-display region DP-NDA of the display panel DP respectively correspond to the display region DA and the non-display region NDA of the display device DD illustrated in FIG. 1.

The display panel DP may include a scan driving circuit SDC, a plurality of signal lines SGL (hereinafter, signal lines), a plurality of signal pads PD (hereinafter, signal pads), and a plurality of pixels PX (hereinafter, pixels). The pixels PX are disposed in the display region DP-DA. The pixels PX each include an organic light-emitting diode and a pixel driving circuit connected thereto.

The scan driving circuit SDC generates a plurality of scan signals (hereinafter, scan signals), and sequentially outputs the scan signals to the plurality of scan lines SL to be described later (hereinafter, scan lines). The scan driving circuit may further output another control signal to the driving circuit of the pixels PX.

The scan driving circuit SDC may include a plurality of thin-film transistors formed through the same process for the driving circuit of the pixels PX, e.g., a low temperature polycrystalline silicon (“LTPS”) process or a low temperature polycrystalline oxide (“LTPO”) process.

The signal lines SGL include the scan lines SL, data lines DL, a power line PL, and a control signal line CSL. The scan lines SL are respectively connected to corresponding pixels PX among the pixels PX, and the data lines DL are respectively connected to corresponding pixels PX among the pixels PX. The power line PL is connected to the pixels PX. The control signal line CSL may provide control signals to the scan driving circuit SDC.

The signal lines SGL may overlap the display region DP-DA and the non-display region DP-NDA. The signal lines SGL may include a pad part and a line part. The line part may overlap the display region DP-DA and the non-display region DP-NDA. The pad part is connected to a terminal of the line part. The pad part is disposed in the non-display region DP-NDA and overlaps a corresponding signal pad among the signal pads PD. In the non-display region DP-NDA, a region in which the signal pads PD are disposed may be defined as a pad region NDA-PD.

The line part connected to the pixel PX substantially constitutes most of the signal lines SGL. The line part is connected to transistors (not illustrated) of the pixel PX. The line part may have a single-layered/multi-layered structure and be a single body or include two or more portions. The two or more portions may be disposed in different layers and be connected to each other via a contact hole passing through an insulating layer disposed between the two or more portions.

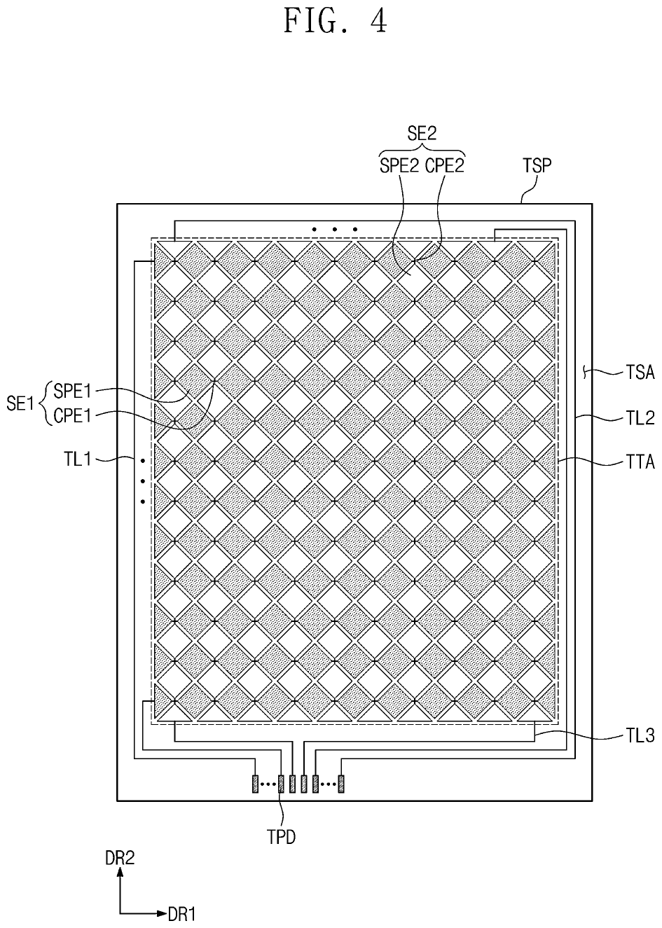

FIG. 4 is a plan view of an embodiment of a touch-sensing panel according to the inventive concept.

Referring to FIG. 4, a touch-sensing panel TSP may detect the touch input TC (refer to FIG. 1) and obtain information about a position or intensity of an external touch input. The touch-sensing panel TSP may include, in a plan view, a touch region TTA and a touch peripheral region TSA. In this embodiment, the touch peripheral region TSA may be defined along a border of the touch region TTA. The touch region TTA and the touch peripheral region TSA of the touch-sensing panel TSP may respectively correspond to the display region DA and the non-display region NDA of the display device DD illustrated in FIG. 1.

The touch-sensing panel TSP includes a plurality of first sensing electrodes SE1, a plurality of second sensing electrodes SE2, a plurality of sensing lines TL1, TL2, and TL3, and a plurality of sensing pads TPD.

The first sensing electrodes SE1 and the second sensing electrodes SE2 are disposed in the touch region TTA. The touch-sensing panel TSP may acquire information about a touch input from changes in capacitance between the first sensing electrodes SE1 and the second sensing electrodes SE2.

The first sensing electrodes SE1 may each extend along the first direction DR1 and be arranged along the second direction DR2. The first sensing electrodes SE1 may include a plurality of first sensing patterns SPE1 and a plurality of first connection patterns CPE1.

The first sensing patterns SPE1 which constitute one first sensing electrode may be arranged to be spaced apart from each other along the first direction DR1. In this embodiment, the first sensing patterns SPE1 are illustrated by shading the first sensing patterns SPE1 for ease of description. The first connection patterns CPE1 may be disposed between the first sensing patterns SPE1 and connect two adjacent first sensing patterns SPE1.

The second sensing electrodes SE2 each extend along the second direction DR2 and are arranged along the first direction DR1. The second sensing electrodes SE2 may include a plurality of second sensing patterns SPE2 and a plurality of second connection patterns CPE2.

The second sensing patterns SPE2 which constitute one second sensing electrode are spaced apart from each other along the first direction DR2. The second connection patterns CPE2 are disposed between the second sensing patterns SPE2 and connect two adjacent second sensing patterns SPE2.

The sensing lines TL1, TL2, and TL3 are disposed in a touch peripheral region TSA. The sensing lines TL1, TL2, and TL3 may include first sensing lines TL1, second sensing lines TL2, and third sensing lines TL3. The first sensing lines TL1 each are connected to the first sensing electrodes SE1. The second sensing lines TL2 each are connected to one-side ends of the second sensing electrodes SE2.

The third sensing lines TL3 each are connected to opposite-side ends of the second sensing electrodes SE2. Opposite-side ends of the second sensing lines SE2 may be opposed to one-side ends of the second sensing electrodes SE2. According to the inventive concept, the second sensing electrodes SE2 may be connected to the second sensing lines TL2 and the third sensing lines TL3. Accordingly, sensitivity in each region may be uniformly maintained for the second sensing electrodes SE2 having a relatively greater length than the first sensing electrodes SE1. This is illustrative. In another embodiment, the third sensing lines TL3 may be omitted, and are not limited to a particular embodiment.

The sensing pads TPD are disposed in the touch peripheral region TSA. The sensing pads TPD are each connected to the sensing lines TL1, TL2, and TL3, and electrically connect external signals to the first sensing electrodes SE1 and the second sensing electrodes SE2. The sensing pads TPD may be connected to the second circuit board FCB2 (refer to FIG. 2B).

FIG. 5 is a side view of an embodiment of a display device according to the inventive concept.

Specifically, FIG. 5 is a cross-sectional view taken along line I-I′ of FIG. 2B.

FIG. 5 illustrates that a display panel DP is a single layer, but the display panel DP may have a multi-layered structure. The display panel DP may include a base layer, a circuit layer, a light-emitting element layer, and an encapsulation layer. Also, those skilled in the art related to this embodiment would understand that the display panel DP may further include other general-purpose components.

FIG. 5 illustrates a stacked structure of a display device DD.

The display device DD may include the display panel DP, an optical unit ARU, a first protective film PF1, a second protective film PF2, a protective panel CP, a support panel SPP, a touch-sensing panel TSP, a cover glass DW, and first to seventh adhesive layers AM1 to AM7. A portion of the first to seventh adhesive layers AM1 to AM7, to be described below, may be omitted. Referring to the drawing, the first and second circuit boards FCB1 and FCB2 may be bent and disposed below the support panel SPP. One surface of the second protective film PF2 may be attached to the seventh adhesive layer AM7.

The display device DD may include a non-bending region NBA and a bending region BA in which the first and second circuit boards FCB1 and FCB2 are bent.

The first adhesive layer AM1 to the seventh adhesive layer AM7 to be described below may be a pressure sensitive adhesive film (“PSA”), an optically clear adhesive film (“OCA”), or an optically clear resin (“OCR”). The first adhesive layer AM1 to the seventh adhesive layer AM7 each include a photocurable adhesive material or a thermosetting adhesive material, and materials thereof are not particularly limited. A potion among the first adhesive layer AM1 to the seventh adhesive layer AM7 may be omitted.

The display panel DP may be disposed between the touch-sensing panel TSP and the protective panel CP. The display panel DP may display an image in response to an electrical signal.

The first circuit board FCB1 may be electrically connected to signal pads PD. In this case, the signal pads PD may correspond to the signal pads PD disposed in the pad region NDA-PD of FIG. 3. The signal pads PD may be disposed on the non-display region DP-NDA (refer to FIG. 2A) of the display panel DP. The first circuit board FCB1 may include the bending region BA which is bendable.

The touch-sensing panel TSP may be disposed on the display panel DP and detect input signals. The second adhesive layer AM2 disposed between the touch- sensing panel TSP and the display panel DP may be omitted. The touch-sensing panel TSP may be disposed between the display panel DP and the optical unit ARU and be electrically connected to the second circuit board FCB2.

A touch control unit TCM may include a touch driving circuit TDC, the second circuit board FCB2, and a sensing pad TPD. The touch control unit TCM may be coupled to a terminal of the touch-sensing panel TSP. The second circuit board FCB2 may be connected to a terminal portion of the touch-sensing panel TSP to electrically connect a main circuit board MCB and the touch-sensing panel TSP. The sensing pad TPD may be disposed on the touch-sensing panel TSP. In this case, the sensing pad TPD may be the same as the sensing pad TPD illustrated in FIG. 4.

The second circuit board FCB2 may be disposed on the display panel DP and be bent together with the first circuit board FCB1. The second circuit board FCB2 may transmit an input signal detected by the touch-sensing panel TSP. The second circuit board FCB2 may overlap the bending region BA and partially overlap the non-bending region NBA.

The optical unit ARU may be disposed on an upper surface of the display panel DP. The optical unit ARU may be disposed on the touch-sensing panel TSP. The optical unit ARU may be disposed between the display panel DP and the cover glass DW and overlap the bending region BA and the non-bending region NBA. According to this embodiment, the optical unit ARU is not disposed only in the non-bending region NBA and may extend up to the bending region BA. As described above, the extended optical unit ARU may serve as a base layer which allows a light-blocking pattern BM and the cover glass DW to be disposed on the bending region BA. Particularly, the optical unit ARU may serve as a base layer when a resin material, such as a resin which forms the cover glass DW, is applied. Additionally, the optical unit ARU may serve as a barrier so as to prevent coating liquid of the cover glass DW from entering the first and second circuit boards FCB1 and FCB2 which are bent.

The optical unit ARU may be disposed on the display panel DP and a portion thereof may be disposed on the second circuit board FCB2. The optical unit ARU may include a first optical portion ARU1 and a second optical portion ARU2.

The first optical portion ARU1 may be disposed on the display panel DP and overlap the non-bending region NBA. The second optical portion ARU2 may be disposed on the second circuit board FCB2 and extend from the first optical portion ARU1 in a direction opposite to the second direction DR2. The second optical portion ARU2 may overlap the bending region BA and overlap a portion of the non-bending region NBA.

The first optical portion ARU1 may be attached to the touch-sensing panel TSP via the first adhesive layer AM1. However, the first adhesive layer AM1 may be omitted when desired. The second optical portion ARU2 may extend from the first optical portion ARU1 and be directly disposed on the second circuit board FCB2 without an additional adhesive layer. This is for the purpose of preventing the bending of the second circuit board FCB2, with which the second optical portion ARU2 is in contact, from being interfered when the second circuit board FCB2 is bent together with the first circuit board FCB1. When bending the second circuit board FCB2, when the second circuit board FCB2 and the second optical portion ARU2 are bonded via an adhesive layer, stress may be applied to the second optical portion ARU2 and the second circuit board FCB2 during a bending process. Thus, the second circuit board FCB2 or the second optical portion ARU2 may be damaged. The first optical portion ARU1 may correspond to a later-described optical member, and the second optical portion ARU2 may correspond to a later-described dummy member. The first optical portion ARU1 and the second optical portion ARU2 may include different materials from each other, and the second optical portion ARU2 may have a transmittance equal to or smaller than that of the first optical portion ARU1.

In an embodiment of the inventive concept, in the optical unit ARU, a stepped portion corresponding to the second circuit board FCB2 may be defined.

In an embodiment of the inventive concept, the thickness T1 of the first optical portion ARU1 may be greater than the thickness T2 of the second optical portion ARU2. The thickness T1 of the first optical portion ARU1 may be greater than the thickness of the second circuit board FCB2. However, the inventive concept is not limited thereto. The thickness T1 of the first optical portion ARU1 and the thickness T2 of the second optical portion ARU2 may be the same, and are not limited to a particular embodiment.

In an embodiment of the inventive concept, a stepped portion SP may be defined in a boundary between the first optical portion ARU1 and the second optical portion ARU2. The stepped portion SP may be spaced apart from a side surface FCB2-S of the second circuit board FCB2 by a predetermined interval. A side surface of the first optical portion ARU1 defining the stepped portion SP may be closer to a center of the non-bending region NBA than the side surface FCB2-S of the second circuit board FCB2 is to the center of the non-bending region NBA. Accordingly, it is possible to prevent the side surface FCB2-S of the second circuit board FCB2 from colliding with the side surface of the first optical portion ARU1 during the bending process. However, the inventive concept is not limited thereto. The stepped portion SP may contact the side surface FCB2-S of the second circuit board FCB2, and is not limited to a particular embodiment.

A first protective film PF1 may be disposed on a rear surface DP-LS of the display panel DP. The display panel DP may be attached to the first protective film PF1 via the third adhesive layer AM3. The protective panel CP may be disposed on a rear surface of the first protective film PF1. A barrier layer BF may be attached to the rear surface of the first protective film PF1 via the fourth adhesive layer AM4.

A cushion layer CU may be attached to a rear surface of the barrier layer BF via the fifth adhesive layer AM5. A support panel SPP may be attached to a rear surface of the cushion layer CU via the sixth adhesive layer AM6.

A driving control module DCM may be coupled to a terminal of the display panel DP. The driving control module DCM may include a first circuit board FCB1, a panel driving circuit PDC, and a main circuit board MCB. The first circuit board FCB1 may electrically connect the main circuit board MCB and the display panel DP, and have a panel driving circuit PDC disposed (e.g., mounted) thereon. In this embodiment, it is illustrated that the panel driving circuit PDC is disposed (e.g., mounted) on the first circuit board FCB1, but a position of the panel driving circuit PDC may not be limited thereto. In an embodiment, the panel driving circuit PDC may be directly disposed on an upper surface DP-US of the display panel DP, for example.

A light-blocking pattern BM may be directly disposed on the optical unit ARU. The light-blocking pattern BM may overlap the non-bending region NBA and the bending region BA of the display panel DP. The light-blocking pattern BM blocks light, and thus it is possible to prevent structures, such as the display panel DP and signal lines disposed below the light-blocking pattern BM, from being visible from the outside. The light-blocking pattern BM may be formed by being printed on the optical unit ARU. An outer side surface BM-O of the light-blocking pattern BM may be aligned with an outer side surface ARU-O of the optical unit ARU. That is, the outer side surface BM-O of the light-blocking pattern BM and the outer side surface ARU-O of the optical unit ARU may be arranged in a straight line in a cross-section.

The cover glass DW may be disposed on the optical unit ARU without an additional adhesive layer or adhesive member. The cover glass DW may be formed by applying a resin material such as resin and then curing the material. On a lower surface of the cover glass DW, a stepped portion corresponding to the light-blocking pattern BM may be defined. An upper surface of the cover glass DW may be flat although the lower surface thereof has a stepped portion caused by the optical unit ARU and the light-blocking pattern BM. An outer side surface DW-O of the cover glass DW may be aligned with the outer side surface BM-O of the light-blocking pattern BM and the outer side surface ARU-O of the optical unit ARU. Accordingly, it is possible to prevent the cover glass DW, the light-blocking pattern BM, and the optical unit ARU from being separated due to an external impact. However, the inventive concept is not limited thereto. The stepped portion may not be defined on the lower surface of the cover glass DW, and is not limited to a particular embodiment.

The first protective film PF1 may be disposed on a rear surface DP-LS of the display panel DP. The first protective film PF1 may be attached to the rear surface DP-LS via the third adhesive layer AM3. However, the third adhesive layer AM3 may be omitted when desired. The first protective film PF1 may protect the rear surface DP-LS of the display panel DP against an external impact.

The protective panel CP may be disposed on the rear surface DP-LS of the display panel DP. The protective panel CP may protect the display panel DP against an impact applied from therebelow.

The protective panel CP may include a fourth adhesive layer AM4, a barrier layer BF, a fifth adhesive layer AM5, a cushion layer CU, and a sixth adhesive layer AM6. The barrier layer BF may be attached to a lower surface of the first protective film PF1 via the fourth adhesive layer AM4. The barrier layer BF has a color having relatively low light transmittance, and thus may prevent components below the barrier layer BF from being visible.

The barrier layer BF may include a flexible synthetic resin film. In an embodiment, the barrier layer BF may be a film including polyimide (“PI”), polyethylene terephthalate (“PET”), or the like, for example. However, a material of the barrier layer BF is not limited thereto, and the barrier layer BF may have various materials when desired.

The cushion layer CU may be attached to a lower surface of the barrier layer BF via the fifth adhesive layer AM5. The cushion layer CU may absorb an impact transmitted from below the display panel DP. The cushion layer CU may be a material having relatively high elasticity, such as a foamed sheet in which multiple openings are defined.

The support panel SPP may be disposed on the lower surface of the protective panel CP and support the display panel DP and the protective panel CP. The support panel SPP may be a metal plate having a rigidity greater than a predetermined value. In an embodiment, the support panel SPP may be a stainless steel plate, for example. The support panel SPP may have a black color so as to block external light incident onto the display panel DP.

Referring to the drawing, the first and second circuit boards FCB1 and FCB2 may be bent and disposed below the support panel SPP. One surface of the second protective film PF2 may be attached to the seventh adhesive layer AM7.

The first circuit board FCB1 may be bent. One end of the first circuit board FCB1 may be disposed on a front surface of the display panel DP, and an opposite end of the first circuit board FCB1 may be disposed on a rear surface of the display panel DP. An opposite end of the first circuit board FCB1 may be connected to the main circuit board MCB.

The second circuit board FCB2 may be connected to a terminal portion of the touch-sensing panel TSP to electrically connect the main circuit board MCB and the touch-sensing panel TSP. The second circuit board FCB2 may transmit an input signal detected by the touch-sensing panel TSP. The second circuit board FCB2 may be bent together with the first circuit board FCB1. One end of the second circuit board FCB2 may be disposed on a front surface of the touch-sensing panel TSP, and an opposite end of the second circuit board FCB2 may be disposed on a rear surface of the touch-sensing panel TSP. An opposite end of the second circuit board FCB2 may be connected to the main circuit board MCB.

The optical unit ARU may cover, in a plan view, a bent portion of the first circuit board FCB1 and a bent portion of the second circuit board FCB2. Since the light-blocking pattern BM is on the optical unit ARU, a bent portion of the display panel DP may be invisible from the outside. The outer side surface ARU-O of the optical unit ARU may further protrude outward than a location LFCB1 farthest from the non-bending region NBA among bent portions of the first circuit board FCB1. The outer side surface ARU-O of the optical unit ARU may further protrude outward than a location LFCB2 farthest from the non-bending region NBA among bent portions of the second circuit board FCB2.

A position in the second direction DR2 of a location LARU, which is farthest from the non-bending region NBA in the optical unit ARU may be defined as a (1-1)-th position HH1. A position in the second direction DR2 of the location LFCB2, which is farthest from the non-bending region NBA among bent portions of the second circuit board FCB2, may be defined as a (2-1)-th position HH2. A position in the second direction DR2 of a location LFCB1, which is farthest from the non-bending region NBA among bent portions of the first circuit board FCB1, may be defined as a (3-1)-th position HH3. The (1-1)-th position HH1 may be disposed farther away from the non-bending region NBA than the (2-1)-th position HH2 and the (3-1)-th position HH3. The (2-1)-th position HH2 may be disposed farther away from the non-bending region NBA than the (3-1)-th position HH3.

The light-blocking pattern BM may cover, in a plan view, a bent portion of the first circuit board FCB1 and a bent portion of the second circuit board FCB2. The outer side surface BM-O of the light-blocking pattern BM may further protrude outward than the location LFCB1 farthest from the non-bending region NBA among the bent portions of the first circuit board FCB1.

When the cover glass DW is formed by applying and then curing a resin material such as a resin, it may be substantially difficult to separately couple the light-blocking pattern BM to a rear surface of the cover glass DW. Accordingly, it may be desired for the light-blocking pattern BM to be disposed on an upper surface of the optical unit ARU disposed under the cover glass DW. In this case, when the optical unit ARU does not extend to the bending region BA like typical optical units, the light-blocking pattern BM may not also extend to the bending region BA. In this case, the first circuit board FCB1 and the second circuit board FCB2 which are bent may be viewed from the outside. In the optical unit ARU in an embodiment of the inventive concept, a stepped portion is formed and extends to the bending region BA. Accordingly, the light-blocking pattern BM may also extend to the bending region BA, and the first circuit board FCB1 and the second circuit board FCB2 which are bent may not be viewed from the outside.

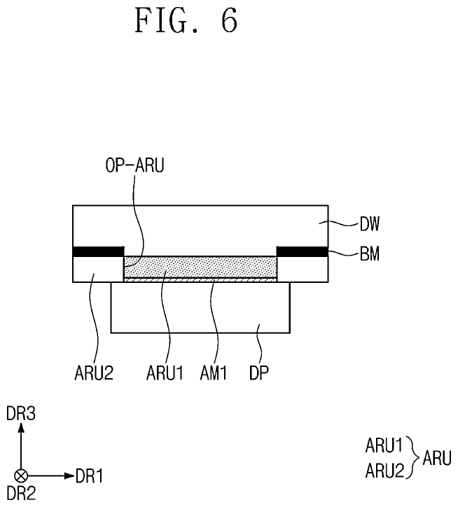

FIG. 6 is an enlarged view of an embodiment of an optical unit according to the inventive concept. Specifically, FIG. 6 is a view illustrating that in the display device DD (refer to FIG. 2A), the optical unit ARU, the display panel DP, and the cover glass DW are enlarged and the adhesive layers are omitted.

Referring to FIG. 6, the optical unit ARU may be disposed between a display panel DP and a cover glass DW. The optical unit ARU may include an optical member ARU1 and a dummy member ARU2. The optical member ARU1 may correspond to the above-described first optical portion ARU1 (refer to FIG. 5), and the dummy member ARU2 may correspond to the above-described second optical portion ARU2 (refer to FIG. 5).

A first adhesive layer AM1 may be provided between the display panel DP and the optical unit ARU. The first adhesive layer AM1 may contact each of the display panel DP and the optical unit ARU.

The dummy member ARU2 may be disposed between the display panel DP and the cover glass DW. The dummy member ARU2 may be in direct contact with the light-blocking pattern BM. However, the inventive concept is not limited thereto, and the dummy member ARU2 may be in direct contact with the cover glass DW. Additionally, the dummy member ARU2 may be in direct contact with the display panel DP.

The dummy member ARU2 may include an upper surface, a lower surface opposed to the upper surface, an inner side surface extending to the upper surface and the lower surface, an outer side surface opposed to the inner side surface.

An opening OP-ARU may be defined in the inner side surface. The opening OP-ARU may overlap the optical member ARU1 to be described later. Additionally, the opening OP-ARU may overlap the first adhesive layer AM1.

The dummy member ARU2 may more extend in the first direction DR1 than the display panel DP. That is, the outer side surface of the dummy member ARU2 may be further in the outer periphery than the outer side surface of the display panel DP.

The dummy member ARU2 may overlap the above-described display region DP-DA (refer to FIG. 3). The inventive concept is not limited thereto, and the dummy member ARU2 may overlap the non-display region DP-NDA (refer to FIG. 3).

The optical member ARU1 may be disposed between the display panel DP and the cover glass DW. The optical member ARU1 may be in direct contact with the cover glass DW. The first adhesive layer AM1 may be provided between the optical member ARU1 and the display panel DP.

The optical member ARU1 may be accommodated in the opening OP-ARU. The optical member ARU1 may overlap the display region DP-DA (refer to FIG. 3).

The optical member ARU1 and the dummy member ARU2 may include different materials from each other. The transmittance of the dummy member ARU2 may be smaller than or equal to the transmittance of the optical member ARU1.

The dummy member ARU2 may be provided to have a transmittance smaller than or equal to the transmittance of the optical member ARU1, and thus a degree of freedom for material options and design may be increased. This then makes it possible to reduce manufacturing costs and manufacturing time.

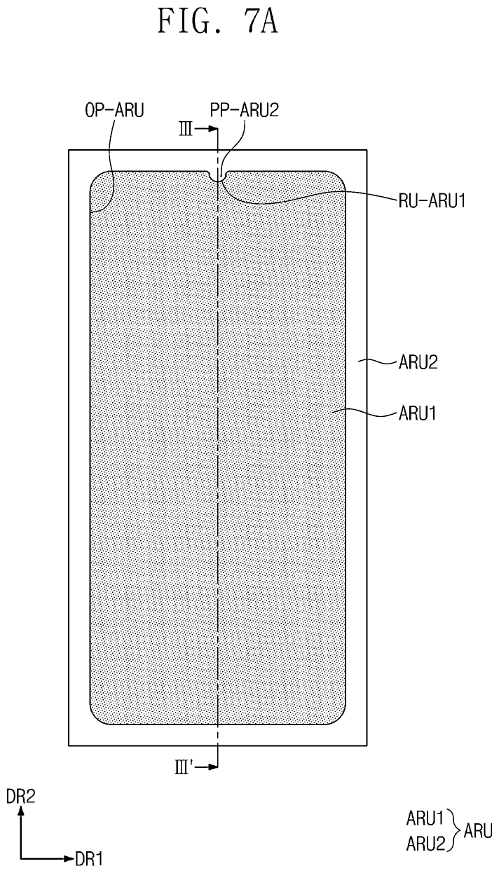

FIGS. 7A and 7B are plan views of an embodiment of an optical unit according to the inventive concept.

Referring to FIG. 7A, an optical member ARU1 may be accommodated in an opening OP-ARU. An outer side surface of the optical member ARU1 may contact an inner side surface of a dummy member ARU2. The optical member ARU1 and the dummy member ARU2 may not overlap in a plan view.

However, the inventive concept is not limited thereto, and the optical member ARU1 and the dummy member ARU2 may overlap in a plan view. That is, in a plan view, the outer side surface of the optical member ARU1 may be disposed between the inner side surface and the outer side surface of the dummy member ARU2.

The dummy member ARU2 may include a projection part PP-ARU2 protruding toward the optical member ARU1. The optical member ARU1 may include a recessed part RU-ARU1 recessed in a position corresponding to the projection part PP-ARU2.

FIG. 7B illustrates a plan view of an embodiment of an optical unit ARU, according to the inventive concept, different from that of FIG. 7A. Specifically, in an embodiment illustrated in FIG. 7B, the projection part PP-ARU2 may be omitted in the dummy member ARU1-2 of an optical unit ARU-1, and the recessed part RU-ARU1 may be omitted in the optical member ARU1-1 of the optical unit ARU-1.

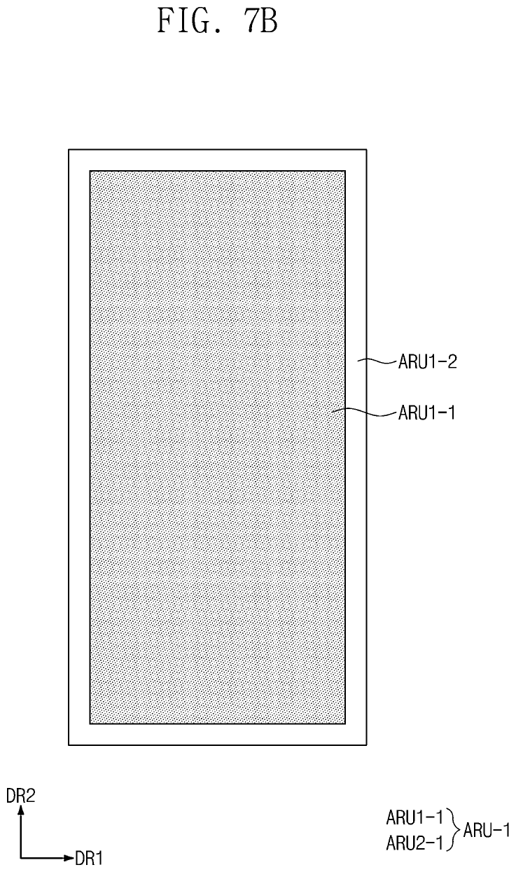

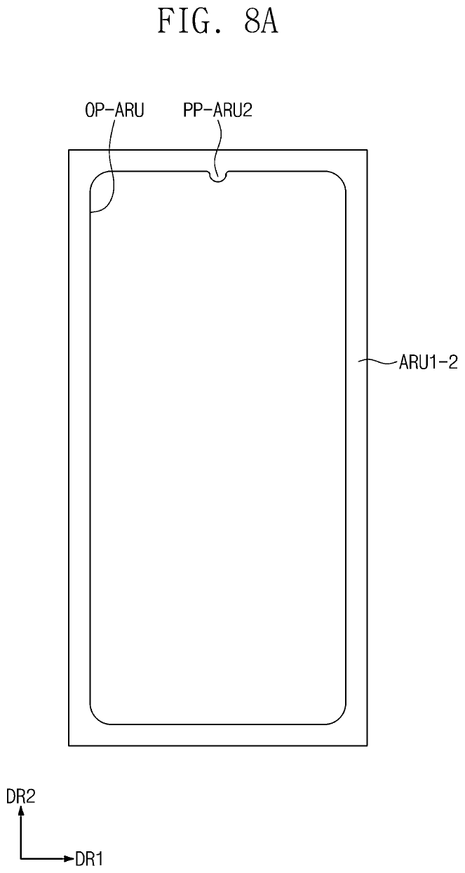

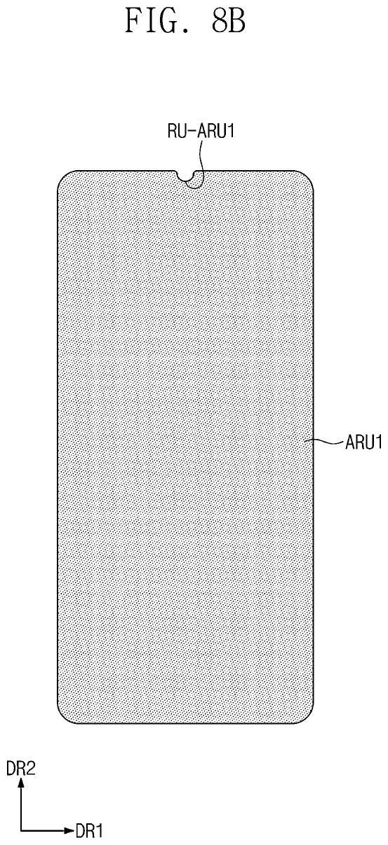

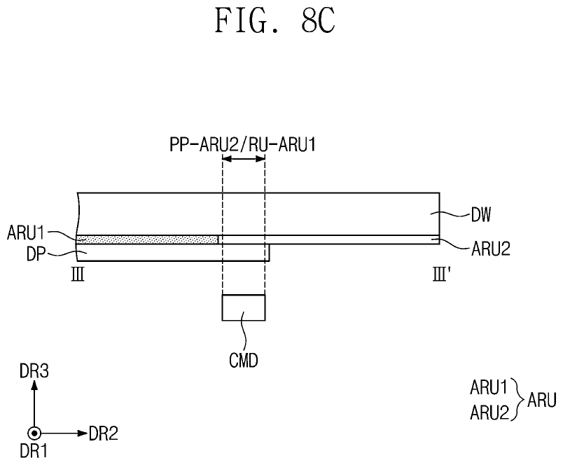

FIG. 8A is a plan view of a dummy member in an embodiment of the inventive concept, FIG. 8B is a plan view of an optical member in an embodiment of the inventive concept, and FIG. 8C is a cross-sectional view of the display device DD (refer to FIG. 2A) according to the inventive concept.

Referring to FIGS. 8A and 8B, a dummy member ARU1-2 may include a projection part PP-ARU2. The projection part PP-ARU2 may be disposed on an inner side surface of the dummy member ARU1-2, and a recessed part RU-ARU1 may be disposed on an outer side surface of an optical member ARU1. The projection part PP-ARU2 and the recessed part RU-ARU1 may contact each other.

The width of the optical member ARU1 in the first direction DR1 may be greater than or equal to the width of an opening OP-ARU in the first direction DR1. Additionally, the width of the optical member ARU1 in the second direction DR2 may be greater than or equal to the width of the opening OP-ARU in the second direction DR2.

When the optical member ARU1 is accommodated in the opening OP-ARU of the dummy member ARU1-2, the optical member ARU may cover an entirety of the opening OP-ARU. This makes it possible for the optical member ARU1 or a dummy member ARU2 to be always in a path of light, going out from the inside to the outside of the display device DD (refer to FIG. 2A), or of light entering from the outside to the inside of the display device DD (refer to FIG. 2A) within a range overlapping the display region DP-DA (refer to FIG. 3).

Referring to FIG. 8C, an electronic module CMD may be disposed below the display panel DP and the optical unit ARU. FIG. 8C illustrates a configuration in which the first adhesive layer AM1 is omitted.

The electronic module CMD may be a camera module, and is not limited thereto. The electronic module CMD may be a sensor module, and is not limited to a particular embodiment.

The electronic module CMD may overlap the dummy member ARU2. The electronic module CMD may not overlap the optical member ARU1.

The electronic module CMD does not overlap the optical member ARU1 and overlaps the dummy member ARU2. Thus, it is possible to prevent polarization or change in path of light caused by the interference of the light going out from the electronic module CMD or entering the electronic module CMD due to the optical member ARU1.

Additionally, the electronic module CMD may overlap, in a plan view, the projection part PP-ARU2 of the dummy member ARU2. The electronic module CMD may not overlap, in a plan view, a recessed part RU-ARU1 of the optical member ARU1.

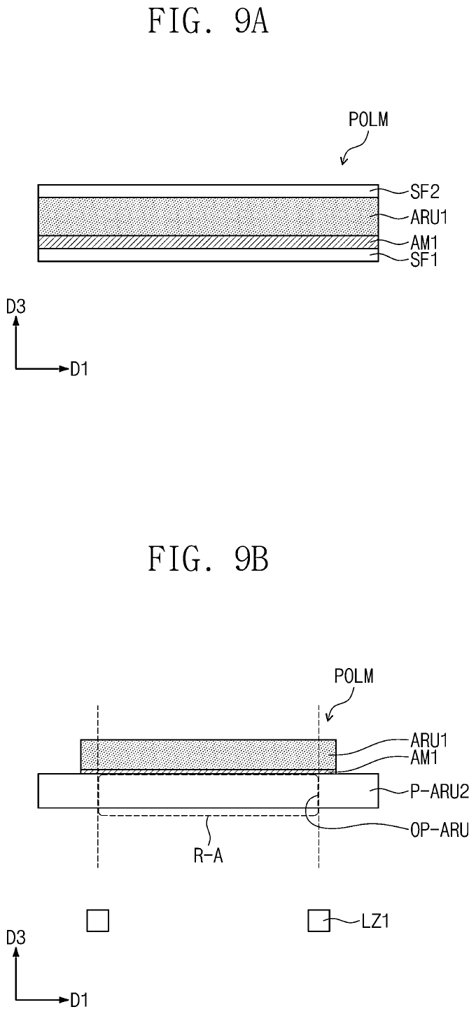

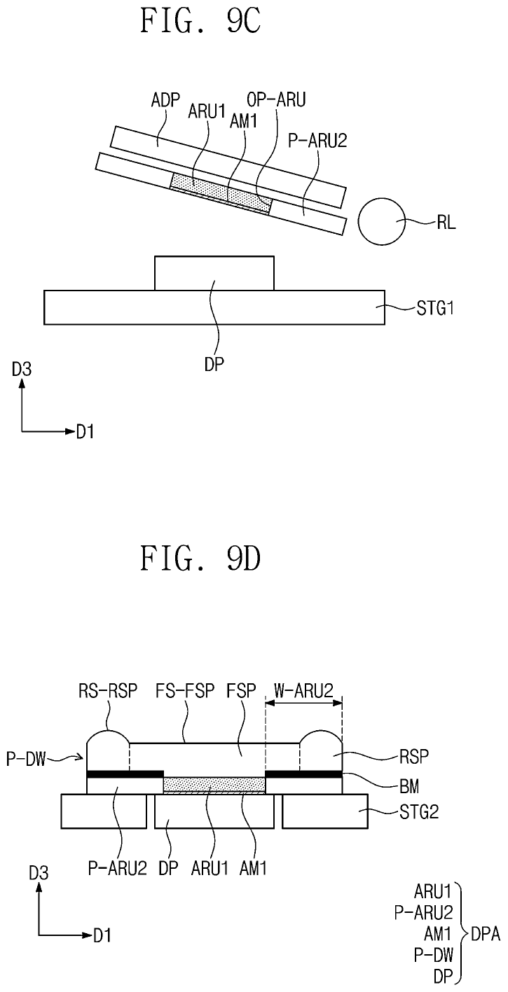

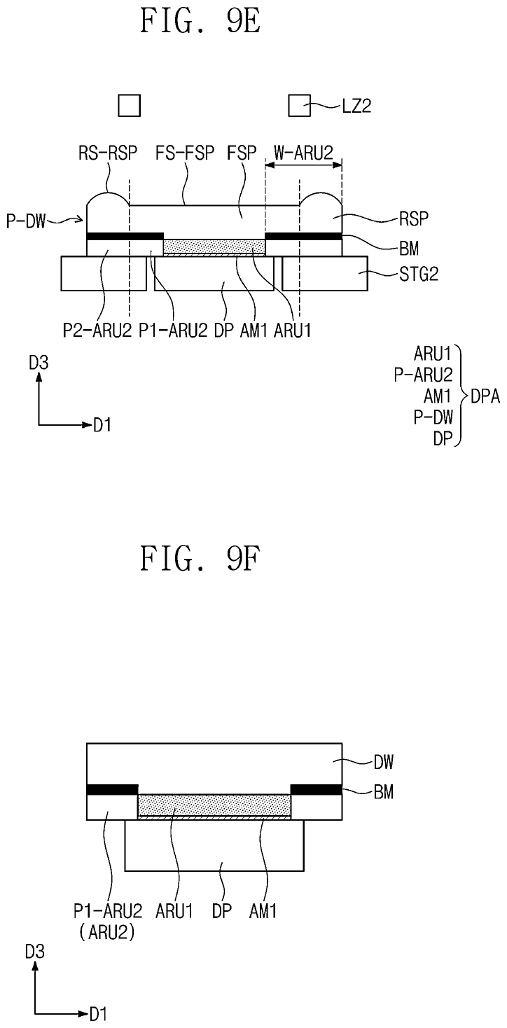

FIGS. 9A to 9F are cross-sectional views illustrating an embodiment of a method for manufacturing the display device DD (refer to FIG. 2A) according to the inventive concept. In description with reference FIGS. 9A to 9F, the same/similar reference numerals or symbols are used for the components same/similar to those described above in FIGS. 1 to 8. A detailed description thereof will be omitted.

In an embodiment of the inventive concept, the method for manufacturing the display device may include disposing, on a preliminary dummy member P-ARU2, an optical member ARU1 including a material different from that of the preliminary dummy member P-ARU2, defining an opening OP-ARU accommodating the optical member ARU1 by removing a portion of the preliminary dummy member P-ARU2, disposing, on a display panel DP, the preliminary dummy member P-ARU2 and the optical member ARU1, forming a preliminary cover glass P-DW covering the preliminary dummy member P-ARU2 and the optical member ARU1, and forming a cover glass DW and a dummy member ARU2 by removing a portion of the preliminary cover glass P-DW and a portion of the preliminary dummy member P-ARU2, which do not overlap the display panel DP.

Referring to FIG. 9A, an optical module POLM may include a first protective film SF1, a first adhesive layer AM1, the optical member ARU1, and a second protective film SF2.

The first protective film SF1 may be disposed below the optical member ARU1. The first protective film SF1 may protect the first adhesive layer AM1 and the optical member ARU1 against external foreign substances.

The first adhesive layer AM1 may be disposed under the optical member ARU1. The first adhesive layer AM1 may be disposed between the first protective film SF1 and the optical member ARU1. The first adhesive layer AM1 may contact each of the first protective film SF1 and the optical member ARU1.

The second protective film SF2 may be disposed on top of the optical member ARU1. The second protective film SF2 may be in direct contact with the optical member ARU1. The second protective film SF2 may protect the optical member ARU1 against external foreign substances.

Referring to FIG. 9B, the optical module POLM in which the protective films SF1 and SF2 are removed may be disposed on the preliminary dummy member P-ARU2. The first adhesive layer AM1 and the optical member ARU1 may be disposed on the preliminary dummy member P-ARU2. In the drawing, a state in which both of the first protective film SF1 and the second protective film SF2 are removed is illustrated. However, only the first protective film SF1 may be removed, and the first protective film SF1 and the second protective film SF2 are not limited to a particular embodiment.

The opening OP-ARU may be defined by removing a portion of the preliminary dummy member P-ARU2, which is a removal portion R-A of the preliminary dummy member P-ARU2. An inner side surface of the preliminary dummy member P-ARU2 may define the opening OP-ARU. The preliminary dummy member P-ARU2 may extend more in the first direction D1 than the optical member ARU1.

The removal portion R-A of the preliminary dummy member P-ARU2 may be removed by first laser LZ1. The first laser LZ1 may remove only the removal portion of the preliminary dummy member P-ARU2.

Referring to FIG. 9C, the display panel DP may be disposed on a first stage STG1. Also, the preliminary dummy member P-ARU2, the optical member ARU1, and the first adhesive layer AM1 may be disposed on the display panel DP. The preliminary dummy member P-ARU2, the optical member ARU1, and the first adhesive layer AM1 may be disposed on the display panel DP using a suction pad ADP. Upper surfaces of the preliminary dummy member P-ARU2 and the optical member ARU1 may be suctioned to the suction pad ADP.

The preliminary dummy member P-ARU2, the optical member ARU1, and the first adhesive layer AM1 are disposed on the display panel DP, and then the upper surfaces of the preliminary dummy member P-ARU2 and the optical member ARU1 may be pressured by a roller RL. In this manner, the preliminary dummy member P-ARU2, the optical member ARU1, and the first adhesive layer AM1 may be attached to the display panel DP.

Referring to FIG. 9D, a preliminary cover glass P-DW may be applied on the preliminary dummy member P-ARU2 and the optical member ARU1. Before the preliminary cover glass P-DW is applied, a light-blocking pattern BM may be formed on the preliminary dummy member P-ARU2. The preliminary cover glass P-DW may be coated on the upper surface of the preliminary dummy member P-ARU2 and the upper surface of the optical member ARU1.

As illustrated in the drawing, the light-blocking pattern BM may be formed on the preliminary dummy member P-ARU2, but is limited thereto. Thus, the light-blocking pattern BM may be formed on the optical member ARU1, and is not limited to a particular embodiment.

When the preliminary cover glass P-DW is applied on the preliminary dummy member P-ARU2 and the optical member ARU1, a portion of the applied preliminary cover glass P-DW may protrude in a direction of getting farther away from the display panel DP.

In an embodiment of the inventive concept, the preliminary cover glass P-DW may include a flat portion FSP and a projection portion RSP. An upper surface FS-FSP of the flat portion FSP may be a flat surface of which a normal direction is the third direction D3. The flat portion FSP may overlap the display panel DP.

An upper surface of the projection portion RSP may be a projection surface RS-RSP protruding in the third direction D3. A portion of the projection portion RSP may not overlap the display panel DP. However, the inventive concept is not limited thereto, and a portion of the projection portion RSP may overlap the display panel DP.

On a plane, the projection portion RSP may be spaced apart from the optical member ARU1 with the flat portion FSP therebetween.

The projection portion RSP may be formed in an edge portion of the preliminary cover glass P-DW. A ratio of a width of the flat portion FSP and a width of the projection portion RSP may vary according to a material included in the preliminary cover glass P-DW. In an embodiment, the ratio of the width of the flat portion FSP and the width of the projection portion RSP may vary due to a surface tension of the preliminary cover glass P-DW according to a material included in the preliminary cover glass P-DW, for example.

In an embodiment, the width of the projection portion RSP of the preliminary cover glass P-DW may be about 5 mm or less, for example.

The material included in the preliminary cover glass P-DW may have physical properties equivalent to those of glass. A spray coating method using a valve (jet printing), a coating using a slit (slit coating), an inkjet method (inkjet printing), etc., may be used for a coating method for the preliminary cover glass P-DW. However, a coating method is not limited thereto, and the preliminary cover glass P-DW may be coated on the preliminary dummy member P-ARU2 and the optical member ARU1 using various methods.

In this manner, a display panel assembly DPA may be formed. The display panel assembly DPA may include the display panel DP, the preliminary cover glass P-DW, the preliminary dummy member P-ARU2, the optical member ARU1, and the first adhesive layer AM1. The display panel assembly DPA may be disposed on a second stage STG2.

Referring to FIGS. 9E and 9F, a portion of the preliminary cover glass P-DW and a portion of the preliminary dummy member P-ARU2 may be removed. Specifically, the projection portion RSP of the cover glass DW and a second dummy portion P2-ARU2 of the preliminary dummy member P-ARU2 overlapping the projection portion RSP may be removed. In addition, the light-blocking pattern BM corresponding thereto may also be removed together.

In an embodiment of the inventive concept, the projection portion RSP of the cover glass DW and the second dummy portion P2-ARU2 of the preliminary dummy member P-ARU2 may be removed by second laser.

The cover glass DW may be formed by removing the projection portion RSP of the preliminary cover glass P-DW. By ensuring that the cover glass DW is constituted only by the flat portion FSP, a surface quality of the cover glass DW may be improved.

A width W-ARU2 of one side of the preliminary dummy member P-ARU2 may be about 5 mm to about 10 mm. Additionally, an interval between the inner side surface and the outer side surface, of the preliminary dummy member P-ARU2, defining the opening OP-ARU may be about 5 mm to about 10 mm.

When the width W-ARU2 of one side of the preliminary dummy member P-ARU2 is made to be about 5 mm to about 10 mm, the projection portion RSP of the preliminary cover glass P-DW may be entirely removed.

Additionally, even when the width W-ARU2 of one side of the preliminary dummy member P-ARU2 is made to be about 5 mm to about 10 mm to remove second dummy portion P2-ARU2, the first dummy portion P1-ARU2 remains, and thus the optical member ARU1 may not be removed.

Further, when the width W-ARU2 of one side of the preliminary dummy member P-ARU2 is made to be about 5 mm to about 10 mm, the second dummy portion P2-ARU2 may be removed by the second laser.

In a display device in an embodiment of the inventive concept, a driving chip may be safely disposed (e.g., mounted) on a board without occurrence of crack or damage.

A display device in an embodiment of the inventive concept makes it possible to achieve an ultra-small size display device and reduce a manufacturing cost.

Although the embodiments of the inventive concept have been described, it is understood that the inventive concept should not be limited to these embodiments but various changes and modifications may be made by one ordinary skilled in the art within the spirit and scope of the inventive concept as hereinafter claimed. Therefore, the technical scope of the inventive concept is not limited to the contents described in the detailed description of the specification, but should be determined by the claims.

What is claimed is:

1. A display panel assembly comprising:
a display panel including a display region and a non-display region adjacent to the display region;
a preliminary cover glass disposed on the display panel;
an optical member disposed between the preliminary cover glass and the display panel, and overlapping the display region; and
a preliminary dummy member which is disposed between the preliminary cover glass and the display panel, and in which an opening accommodating the optical member is defined, the preliminary dummy member comprising:
a first dummy portion which overlaps the non-display region and in which the opening is defined,
a second dummy portion extending, from the first dummy portion, a direction of getting farther away from the opening, and non-overlapping the display panel.

2. The display panel assembly of claim 1, wherein the preliminary cover glass is in direct contact with the optical member and the preliminary dummy member.

3. The display panel assembly of claim 1, wherein the preliminary dummy member and the optical member comprise different materials from each other.

4. The display panel assembly of claim 1, wherein a light transmittance of the preliminary dummy member is smaller than or equal to a light transmittance of the optical member.

5. The display panel assembly of claim 1, wherein a sum of a first width of the first dummy portion and a second width of the second dummy portion is 4 millimeters to 10 millimeters.

6. The display panel assembly of claim 1, further comprising an adhesive member disposed between the optical member and the display panel,
wherein the adhesive member is spaced apart from the preliminary dummy member.

7. The display panel assembly of claim 1, further comprising an electronic module disposed below the display panel,
wherein the electronic module overlaps the first dummy portion and does not overlap the optical member.

8. The display panel assembly of claim 7, wherein the first dummy portion comprises a projection part protruding toward the optical member,
the optical member comprises a recessed part corresponding to the projection part, and
the electronic module overlaps the projection part in a plan view.

9. The display panel assembly of claim 1, wherein the preliminary cover glass comprises:
a flat portion of which an upper surface is defined as a flat surface by a first direction and a second direction crossing the first direction; and
a projection portion which is connected to the flat portion, and of which an upper surface is defined as a projection surface protruding in a third direction crossing the first direction and the second direction, and
the flat portion overlaps the first dummy portion, and the projection portion overlaps the second dummy portion.

10. A display device comprising:
a display panel including a display region and a non-display region adjacent to the display region;
a cover glass disposed on the display panel;
an optical member disposed between the cover glass and the display panel, and overlapping the display region;
a dummy member in which an opening accommodating the optical member is defined, and which is disposed between the cover glass and the display panel and overlaps the non-display region; and
an adhesive member disposed between the optical member and the display panel, and spaced apart from the dummy member.

11. The display device of claim 10, wherein the cover glass is in direct contact with the optical member and the dummy member.

12. The display device of claim 10, wherein a side surface of the cover glass and a side surface of the dummy member are substantially aligned.

13. The display device of claim 10, further comprising an electronic module disposed below the display panel,
wherein the electronic module overlaps the dummy member and does not overlap the optical member.

14. The display device of claim 13, wherein the dummy member comprises a projection part protruding toward the optical member,
the optical member comprises a recessed part corresponding to the projection part, and
the electronic module overlaps the projection part in a plan view.

15. The display device of claim 10, wherein the dummy member and the optical member comprise different materials from each other, and
a light transmittance of the dummy member is smaller than or equal to a light transmittance of the optical member.

16. A method for manufacturing a display device, the method comprising:
disposing, on a preliminary dummy member, an optical member including a material different from a material of the preliminary dummy member;
forming an opening accommodating the optical member by removing a removal part of the preliminary dummy member;
attaching, to a display panel, the preliminary dummy member in which the opening is defined and the optical member;
forming a preliminary cover glass covering the preliminary dummy member in which the opening is formed and the optical member; and
forming a cover glass and a dummy member by removing a portion of the preliminary cover glass not overlapping the display panel, and a portion of the preliminary dummy member in which the opening is defined.

17. The method of claim 16, wherein an interval between an inner side surface, of the preliminary dummy member, defining the opening, and an outer side surface, of the preliminary dummy member, opposed to the inner side surface is 5 millimeters to 10 millimeters.

18. The method of claim 16, wherein on the preliminary cover glass, a flat portion overlapping the optical member and a projection portion overlapping the dummy member are formed, and
the projection portion and a portion of the preliminary dummy member overlapping the projection portion are removed using first laser.

19. The method of claim 16, wherein the disposing the preliminary dummy member and the optical member on the display panel comprises:
moving the optical member and the preliminary dummy member onto the display panel by suctioning the optical member and the preliminary dummy member with a suction pad; and
detaching the suction pad from the preliminary dummy member and the optical member, and then adhering the preliminary dummy member and the optical member to the display panel using a roller.

20. The method of claim 16, wherein in the forming the opening by removing a portion of the preliminary dummy member, the opening is formed using second laser.
